(19) United States
(12) Patent Application Publication
(10) Pub. No.: US 2026/0114175 A1
(43) Pub. Date: Apr. 23, 2026

(54) PHOTON UP-CONVERSION FILM, MANUFACTURING METHOD FOR PHOTON UP-CONVERSION FILM, PHOTON UP-CONVERSION BODY, LAMINATE, AND ENERGY CONVERSION DEVICE

(71) Applicants: NITTO DENKO CORPORATION, Ibaraki-shi, Osaka (JP); WAKAYAMA PREFECTURE, Wakayama-shi, Wakayama (JP)

(72) Inventors: Mami Kawaguchi, Ibaraki-shi (JP); Shinji Iwakiri, Ibaraki-shi (JP); Shoichi Matsuda, Ibaraki-shi (JP); Minoru Miyatake, Ibaraki-shi (JP); Takeshi Mori, Wakayama-shi (JP); Akane Saito, Wakayama-shi (JP); Hitoshi Saomoto, Wakayama-shi (JP); Tomohiro Mori, Wakayama-shi (JP)

(73) Assignees: NITTO DENKO CORPORATION, Ibaraki-shi, Osaka (JP); WAKAYAMA PREFECTURE, Wakayama-shi, Wakayama (JP)

(21) Appl. No.: 19/158,101

(22) PCT Filed: Mar. 22, 2024
(86) PCT No.: PCT/JP2024/011344

§ 371 Date: Aug. 20, 2025

(30) Foreign Application Priority Data
Mar. 31, 2023 (JP) 2023-057644

(51) Int. Cl. H10K 85/10; C08K 5/00; C08K 5/01; C09D 5/22; C09D 7/41; C09D 7/63; C09D 129/04; C09D 171/02; C09K 11/02; C09K 11/06; H10K 50/12; H10K 85/00; H10K 101/60

(52) U.S. Cl. CPC H10K 85/10; C09D 5/22; C09D 7/41; C09D 7/63; C09D 129/04; C09D 171/02; C09K 11/02; C09K 11/06; H10K 50/121; H10K 85/731; C08K 5/0091; C08K 5/01; C08K 2201/014; C09K 2211/1007; C09K 2211/1011; H10K 2101/60

(57) ABSTRACT

Provided are a photon up-conversion film, a photon up-conversion body, a laminate, and an energy conversion device, which are capable of high-efficiency up-conversion, and methods of producing the same. The photon up-conversion film according to an embodiment of the present invention includes a color-forming portion containing at least: a sensitizing component capable of absorbing light in a first wavelength region λ1; and a light-emitting component capable of radiating light in a second wavelength region λ2 including wavelengths shorter than those of the first wavelength region λ1. A relaxation time of the photon up-conversion film measured by a spin-echo method through use of time-domain nuclear magnetic resonance (pulse NMR) at 298 K is less than 210 ms.

### TECHNICAL FIELD

The present invention relates to a photon up-conversion film, a method of producing a photon up-conversion film, a photon up-conversion body, a laminate, and an energy conversion device.

### BACKGROUND ART

A photon up-conversion (hereinafter sometimes simply referred to as “up-conversion”) technology by which low-energy light is converted into high-energy light has been expected to find applications in a wide variety of fields including a solar cell or photovoltaic power generation, a photocatalyst, bioimaging, and an optical instrument. A technology including utilizing triplet-triplet annihilation (TTA) caused by collision between molecules in a triplet state has been known as up-conversion emission in an organic material. In solution-based up-conversion in which a donor compound and an acceptor compound are dissolved in a solvent out of the kinds of up-conversion each utilizing the TTA (TTA-UC), energy exchange is efficiently performed by the diffusion of a molecule of the donor compound and a molecule of the acceptor compound. Meanwhile, there is a problem in that fields in which the solution-based up-conversion can be put into practical use are limited.

In view of such circumstances as described above, the research and development of up-conversion emission in a solid state have been advanced. However, substantially no molecular diffusion occurs in the solid state, and hence there is a problem in that TTA cannot be efficiently utilized. For example, a resin film having introduced thereinto a donor compound and an acceptor compound has been investigated, but its up-conversion emission efficiency is insufficient.

### CITATION LIST

### Patent Literature

[PTL 1] JP 5491408 B2

### SUMMARY OF INVENTION

### Technical Problem

The present invention has been made to solve the above-mentioned problems of the related art, and a primary object of the present invention is to provide a photon up-conversion film, a photon up-conversion body, a laminate, and an energy conversion device, which are capable of high-efficiency up-conversion, and methods of producing the same.

Another object of the present invention is to provide a photon up-conversion film, a photon up-conversion body, a laminate, and an energy conversion device, which enable up-conversion satisfying high transmittance and high efficiency by optimization of a medium, and methods of producing the same.

### Solution to Problem

[1] A photon up-conversion film according to one embodiment of the present invention includes a color-forming portion. The color-forming portion contains at least a sensitizing component and a light-emitting component. The sensitizing component is capable of absorbing light in a first wavelength region λ1. The light-emitting component is capable of radiating light in a second wavelength region λ2 including wavelengths shorter than those of the first wavelength region λ1. A relaxation time of the photon up-conversion film measured by a spin-echo method through use of time-domain nuclear magnetic resonance (pulse NMR) at 298 K is less than 210 ms.
[2] The photon up-conversion film according to the above-mentioned item [1] may further include a matrix. The color-forming portion is dispersed as a dispersion phase in the matrix.
[3] In the photon up-conversion film according to the above-mentioned item [2], the matrix may include a resin.
[4] In the photon up-conversion film according to the above-mentioned item [3], the resin may include polyethylene oxide and/or a polyvinyl alcohol-based resin.
[5] In the photon up-conversion film according to any one of the above-mentioned items [1] to [4], the color-forming portion may contain a solvent having a boiling point of 80° C. or more.
[6] In the photon up-conversion film according to any one of the above-mentioned items [1] to [5], the color-forming portion may contain a solvent having a viscosity at 23° C. of 0.6 mPa·s or more.
[7] In the photon up-conversion film according to any one of the above-mentioned items [1] to [6], the color-forming portion may contain a monomolecular liquid crystal compound.
[8] The photon up-conversion film according to any one of the above-mentioned items [3] to [7] may include 7.00×10⁻⁹ mol to 5.00×10⁻⁶ mol of the sensitizing component, and 5.00×10⁻⁶ mol to 7.00×10⁻⁵ mol of the light-emitting component with respect to 1 g of the resin.
[9] A method of producing a photon up-conversion film according to another aspect of the present invention is a method of producing the photon up-conversion film of any one of the above-mentioned items [1] to [8], the method including the steps of: preparing an emulsion from a medium in which the sensitizing component and the light-emitting component are dispersed and/or dissolved, and an aqueous solution containing a water-soluble resin; applying the emulsion to a substrate to form a coating film; and drying the coating film.
[10] A laminate according to another aspect of the present invention includes the photon up-conversion film of any one of the above-mentioned items [1] to [8].
[11] An energy conversion device according to still another aspect of the present invention includes the photon up-conversion film of any one of the above-mentioned items [1] to [8].
[12] A photon up-conversion body according to still another aspect of the present invention includes a color-forming portion. The color-forming portion contains at least a sensitizing component and a light-emitting component. The sensitizing component is capable of absorbing light in a first wavelength region λ1. The light-emitting component is capable of radiating light in a second wavelength region λ2 including wavelengths shorter than those of the first wavelength region λ1. A relaxation time of the photon up-conversion film measured by a spin-echo method through use of time-domain nuclear magnetic resonance (pulse NMR) at 298 K is less than 210 ms.

### Advantageous Effects of Invention

According to the embodiments of the present invention, the photon up-conversion film, the photon up-conversion body, the laminate, and the energy conversion device, which are capable of high-efficiency up-conversion, and the methods of producing the same can be achieved. In addition, the photon up-conversion film, the photon up-conversion body, the laminate, and the energy conversion device, which enable high transmittance and high efficiency up-conversion by optimization of the medium, and the methods of producing the same can be achieved.

### BRIEF DESCRIPTION OF DRAWINGS

FIG. 1 is a conceptual view of an energy level for describing the mechanism of up-conversion.

### DESCRIPTION OF EMBODIMENTS

Embodiments of the present invention are described below. However, the present invention is not limited to these embodiments.

### A. Mechanism of Photon Up-conversion

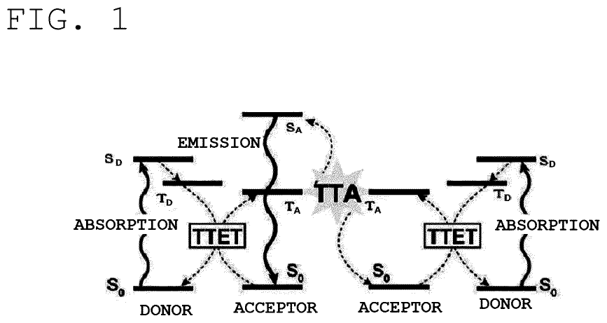

The mechanism of photon up-conversion is described with reference to FIG. 1. First, a sensitizing component (donor) absorbs incident light, and hence an excited triplet state T_{D} is produced by intersystem crossing from an excited singlet state S_{D}. Next, triplet-triplet energy transfer (TTET) from the donor to a light-emitting component (acceptor) occurs to produce the excited triplet state T_{A} of the acceptor. Next, the molecules of the acceptor in the excited triplet state T_{A} diffuse and collide with each other, or approach each other within a range that is capable of energy transfer, to cause triplet-triplet annihilation (TTA). As a result, a high excited singlet energy state S_{A} of the acceptor is produced. Up-conversion light (light having energy larger than that of excited light) is emitted from the high excited singlet energy state S_{A}.

### B. Entire Configuration of Photon Up-Conversion Film

A photon up-conversion film (hereinafter sometimes referred to as “up-conversion film”) according to an embodiment of the present invention includes a color-forming portion. The color-forming portion contains at least a sensitizing component (donor) and a light-emitting component (acceptor). The sensitizing component is capable of absorbing light in a first wavelength region λ1. The light-emitting component is capable of radiating light in a second wavelength region λ2 including wavelengths shorter than those of the first wavelength region λ1. Typically, the sensitizing component and the light-emitting component are positioned close to each other so as to enable energy transfer.

When the relaxation time of such photon up-conversion film measured by a spin-echo method through use of time-domain nuclear magnetic resonance (TD-NMR, pulse NMR) at 298 K (24.85° C.) is less than 210 milliseconds (ms), the absolute quantum yield of the up-conversion film can be improved. Accordingly, an up-conversion film capable of high-efficiency up-conversion can be achieved. In addition, there can be produced an up-conversion film that is highly efficient while being improved in transmittance by optimization of a medium.

In one embodiment, the photon up-conversion film further includes a matrix. The color-forming portion is dispersed as a dispersion phase in the matrix. The photon up-conversion film typically has a sea-island structure.

The domain size of the color-forming portion is, for example, from 0.05 μm to 10 μm, preferably from 0.1 μm to 10 μm, more preferably from 0.1 μm to 5.0 μm, still more preferably from 1.0 μm to 5.0 μm. The domain size of the color-forming portion is, for example, measured by observation of its cross section with a scanning electron microscope (SEM) or observation of its surface with an optical microscope. When the domain size of the color-forming portion falls within such ranges, the emission efficiency of the up-conversion film can be stably improved.

The content of the color-forming portion in the up-conversion film is, for example, from 1.0 vols to 60 vol %, preferably from 5.0 volt to 50 volt. The content of the color-forming portion is measured by, for example, any appropriate image processing from a cross-sectional SEM image. When the content of the color-forming portion falls within such ranges, the emission efficiency of the up-conversion film can be more stably improved.

The thickness of the up-conversion film is, for example, from 5 μm to 200 μm, preferably from 10 μm to 150 μm, more preferably from 15 μm to 100 μm. When the thickness of the up-conversion film falls within such ranges, the color-forming portion can be satisfactorily dispersed over an entire region in the thickness direction of the film, and desired up-conversion can be stably achieved.

### C. Details of Photon Up-Conversion Film

As described above, the relaxation time (average relaxation time) of the photon up-conversion film measured by TD-NMR at 298 K (24.85° C.) is less than 210 ms, preferably 150 ms or less, more preferably 90 ms or less, still more preferably 80 ms or less. For example, a spin-echo method is adopted as a method of measuring the relaxation time (average relaxation time). The lower limit of the relaxation time (average relaxation time) measured by TD-NMR at 298 K is typically 20 us or is typically 6 μs. The details of the method of measuring the relaxation time (average relaxation time) are described in Examples to be described later.

When the relaxation time by TD-NMR at 298 K falls within such ranges, the color-forming portion in the up-conversion film is assumed to be present in a form capable of efficient energy transfer at 298 K. In addition, it is assumed that a high-efficiency up-conversion light-emitting body can be obtained by reducing energy loss by nonradiative deactivation in the color-forming portion. Accordingly, molecular diffusion of the sensitizing component and the light-emitting component can occur in the color-forming portion, and hence energy can be efficiently exchanged.

In one embodiment, the color-forming portion contains a medium capable of dissolving and/or dispersing the sensitizing component and the light-emitting component. Accordingly, smooth molecular diffusion of the sensitizing component and the light-emitting component can be achieved in the color-forming portion, and the emission efficiency of the up-conversion film can be further improved.

### D. Medium of Color-Forming Portion

Examples of the medium include a monomolecular liquid crystal compound and/or a solvent. The media may be used alone or in combination thereof.

When the color-forming portion contains a monomolecular liquid crystal compound, the absolute quantum yield of the up-conversion film can be further improved.

The monomolecular liquid crystal compound may exhibit liquid crystallinity or crystallinity at 298 K (24.85° C.). The monomolecular liquid crystal compound may be a nematic liquid crystal compound, may be a smectic liquid crystal compound, or may be a cholesteric liquid crystal compound. The monomolecular liquid crystal compound is preferably a nematic liquid crystal compound.

The monomolecular liquid crystal compound exhibiting liquid crystallinity at 298 K (hereinafter sometimes referred to as “normal-temperature liquid crystal compound”) is typically capable of dissolving the sensitizing component and the light-emitting component.

Examples of the normal-temperature liquid crystal compound include cyanobiphenyls, cyanophenyl cyclohexane esters, alkoxyphenyl tolans, and Schiff bases. The normal-temperature liquid crystal compounds may be used alone or in combination thereof.

Of the normal-temperature liquid crystal compounds, cyanobiphenyls, cyanophenyl cyclohexane esters, and alkoxyphenyl tolans are preferred examples.

Examples of the cyanobiphenyls include 4-cyano-4′-alkylbiphenyls, such as 4-cyano-4′-pentylbiphenyl, 4-cyano-4′-hexylbiphenyl, 4-cyano-4′-heptylbiphenyl, and 4-cyano-4′-n-octylbiphenyl.

Examples of the cyanophenyl cyclohexane esters include 4-cyano-4′-alkylphenyl cyclohexane esters, such as a 4-cyano-4′-pentylphenyl cyclohexane ester, a 4-cyano-4′-butylphenyl cyclohexane ester, and a 4-cyano-4′-propylphenyl cyclohexane ester.

Examples of the alkoxyphenyl tolans include 4-alkoxy-4′-alkylphenyl tolans, such as 4-ethoxy-4′-butylphenyl tolan, 4-methoxy-4′-ethylphenyl tolan, and 4-butoxy-4′-propylphenyl tolan.

The monomolecular liquid crystal compound exhibiting crystallinity at 298 K (hereinafter sometimes referred to as “high-temperature liquid crystal compound”) may be capable of forming a solid solution with the sensitizing component and the light-emitting component, or may be capable of dispersing the sensitizing component and the light-emitting component at 298 K (24.85° C.).

Examples of the high-temperature liquid crystal compound include cyanophenyl cyclohexanes, cyanophenyl esters, alkoxyphenyl esters, alkoxyphenyl cyclohexane esters, and alkoxycyanobiphenyls. The high-temperature liquid crystal compounds may be used alone or in combination thereof.

Of the high-temperature liquid crystal compounds, cyanophenyl cyclohexanes, cyanophenyl esters, alkoxyphenyl esters, alkoxyphenyl cyclohexane esters, and alkoxycyanobiphenyls are preferred examples.

Examples of the cyanophenyl cyclohexanes include 4-cyano-4′-alkylphenyl cyclohexanes, such as 4-cyano-4′-pentylphenyl cyclohexane and 4-cyano-4′-propylphenyl cyclohexane.

Examples of the cyanophenyl esters include 4-cyano-4′-alkylphenyl esters, such as a 4-cyano-4′-nonylphenyl ester, a 4-cyano-4′-ethylphenyl ester, and a 4-cyano-4′-butylphenyl ester.

Examples of the alkoxyphenyl esters include 4-alkyl-4′-alkoxyphenyl esters, such as a 4-pentyl-4′-hexyloxyphenyl ester, a 4-pentyl-4′-methoxyphenyl ester, and a 4-ethyl-4′-hexyloxyphenyl ester.

Examples of the alkoxyphenyl cyclohexane esters include 4-alkoxy-4′-alkylphenyl cyclohexane esters, such as a 4-methoxy-4′-pentylphenyl cyclohexane ester, a 4-ethoxy-4′-butylphenyl cyclohexane ester, and a 4-ethoxy-4′-propylphenyl cyclohexane ester.

Examples of the alkoxycyanobiphenyls include 4-cyano-4′-alkoxybiphenyls, such as 4-cyano-4′-pentoxybiphenyl, 4-cyano-4′-butoxybiphenyl, and 4-cyano-4′-ethoxybiphenyl.

The solvent is typically in a liquid state at 298 K (24.85° C.). The solvent may be in a solid state at 298 K (24.85° C.), and a material having such a melting point that the material is brought into a liquid state in the process of production of an up-conversion film or an up-conversion body, or a material whose melting point can be reduced by mixing an organic solvent may be similarly used as the solvent. The solvent is typically capable of dissolving the sensitizing component and the light-emitting component.

The viscosity at 23° C. of the solvent is, for example, 0.6 mPa's or more, preferably 4.0 mPa or more. The viscosity of the solvent may be measured as the solution viscosity (mPa·s) of a coating liquid at a shear rate of 800 rpm under the condition of 23° C. through use of any appropriate viscosity-viscoelasticity measurement device (e.g., a rheometer available under the product name “RS-600” from HAAKE).

The boiling point of the solvent is, for example, 60° C. or more, preferably 80° C. or more, more preferably 150° C. or more, still more preferably 200° C. or more. The upper limit of the boiling point of the solvent is typically 300° C. or is typically 400° C. When a mixture of a plurality of solvents is used as the medium, the temperature at which a weight reduction ratio is 95% when the mixed solvent is heated from 30° C. to 400° C. at 10° C./min through use of TG/DTA is defined as the boiling point of the mixed solvent.

When the viscosity and/or boiling point of the solvent in the color-forming portion falls within such ranges, the solvent is less liable to volatilize in the production process, and energy loss by nonradiative deactivation can be suppressed. Accordingly, the absolute quantum yield of the up-conversion film can be further improved.

An example of the solvent is an organic solvent, and more specific examples thereof include phthalic acid esters, glycerin, a triglyceride compound, and an ionic liquid. The solvents may be used alone or in combination thereof. Of the solvents, phthalic acid esters and a triglyceride compound are preferred examples.

Examples of the phthalic acid esters include dimethyl phthalate, dibutyl phthalate, and dioctyl phthalate.

Examples of the triglyceride compound include tricaprin (1, 2, 3-tridecanoylglycerol), triacetin (glycerol triacetate), tricaprylin (glycerol tri-n-octanoate), and tricaproin (glycerol trihexanoate).

Of those media, the normal-temperature liquid crystal compound is preferred. When the medium contains the normal-temperature liquid crystal compound, the emission efficiency of the up-conversion film can be even further improved.

The medium may contain an additive. Examples of the additive include: fatty acid oils such as MCT oil; and saturated hydrocarbons, such as hexadecane and liquid paraffin. A material that does not have high dye solubility is defined as the additive unlike the solvent. The expression “not having high dye solubility” means that when a dye is added to the additive at normal temperature and normal pressure (23° C. and 0.1 MPa) and then mixed, a dye dissolution concentration is, for example, 0.1 mM or less. The viscosity, refractive index, and phase transition temperature of the medium can be suitably adjusted because the medium contains the additive.

### E. Matrix

Examples of a material for the matrix include a resin and glass.

In one embodiment, the matrix includes a resin. The resin is typically a water-soluble resin.

Any appropriate water-soluble resin may be used as the water-soluble resin as long as the matrix is formed. Specific examples of the water-soluble resin include a polystyrene sulfonic acid salt, polyethylene oxide, a polyethyleneimine, a polyvinyl alcohol-based resin, and a cellulose-based resin. An example of the polystyrene sulfonic acid salt is sodium polystyrene sulfonate. An example of the polyethyleneimine is a polyethyleneimine hydrochloric acid salt. Examples of the polyvinyl alcohol-based resin include polyvinyl alcohol, amine-modified polyvinyl alcohol, and carboxylic acid-modified polyvinyl alcohol. An example of the cellulose-based resin is hydroxyethyl cellulose.

Of such water-soluble resins, polyethylene oxide and a polyvinyl alcohol-based resin are preferred examples, and a polyvinyl alcohol-based resin is a more preferred example.

When the resin for forming the matrix includes polyethylene oxide and/or a polyvinyl alcohol-based resin, the emission efficiency of the up-conversion film can be stably improved.

A Hansen solubility parameter (HSP) distance Ra between the resin for forming the matrix, and each of the sensitizing component and the light-emitting component is, for example, 10 (MPa)^{1/2} or more, or for example, 11 (MPa)^{1/2} or more, preferably 12 (MPa)^{1/2} or more, more preferably 15 (MPa)^{1/2} or more, still more preferably 18 (MPa)^{1/2} or more. Meanwhile, the HSP distance Ra between the resin for forming the matrix, and each of the sensitizing component and the light-emitting component is, for example, 25 (MPa)^{1/2}, preferably 23 (MPa)^{1/2} or more, more preferably 21 (MPa)^{1/2} or less. The fact that the HSP distance Ra falls within such ranges means that an affinity between the resin for forming the matrix, and each of the sensitizing component and the light-emitting component is low. As a result, the movement of each of the sensitizing component and the light-emitting component into the matrix is significantly suppressed, and hence the sensitizing component and the light-emitting component can be caused to be stably present in the color-forming portion.

A HSP is represented by a vector obtained by dividing a Hildebrand solubility parameter into three components, that is, a dispersion force (δD), a permanent dipole intermolecular force (δP), and a hydrogen bonding force (δH), and plotting the components in a three-dimensional space. Components whose vectors obtained as described above are similar to each other can be judged to have high solubilities. That is, a degree of similarity between the solubilities can be judged from the HSP distance Ra between the components. The definition and calculation of the HSP are described in “Hansen Solubility Parameters: A User's Handbook” written by Charles M. Hansen (CRC Press, LLC, 2007). Known values are available as the HSP values of various resins and solvents, and these values may be used as they are, or values calculated by using Hansen Solubility Parameters in Practice (HSPiP) that is computer software may be used. The HSPIP includes databases for resins and solvents.

The HSP distance Ra between the resin (HSP value: δD_{R}, δP_{R}, δH_{R}) and the sensitizing component or the light-emitting component (HSP value: δD_{C}, δP_{C}, δH_{C}) may be calculated from the equation (1).

$$Ra = {\{ 4 \times {( δ {D}_{R} - δ {D}_{C} )}^{2} + {( δ {P}_{R} - δ {P}_{C} )}^{2} + {( δ {H}_{R} - δ {H}_{C} )}^{2} \}}^{1 / 2} \qquad ( 1 )$$

In the equation (1), δD_{R} represents the dispersion force of the resin, δP_{R} represents the permanent dipole intermolecular force of the resin, δH_{R} represents the hydrogen bonding force of the resin, δD_{C} represents the dispersion force of the sensitizing component or the light-emitting component, δP_{C} represents the permanent dipole intermolecular force of the sensitizing component or the light-emitting component, and δH_{C} represents the hydrogen bonding force of the sensitizing component or the light-emitting component.

### F. Sensitizing Component and Light-Emitting Component

### F-1. Sensitizing Component

As is apparent from the mechanism described in the section A-1, the sensitizing component absorbs light (incident light), is brought into an excited triplet state by intersystem crossing from an excited singlet state, and causes triplet-triplet energy transfer in the light-emitting component. The sensitizing component is, for example, a compound having a porphyrin structure, a phthalocyanine structure, or a fullerene structure. Such compound may contain a metal atom in a molecule thereof. Examples of the metal atom include Pt, Pd, Zn, Ru, Re, Ir, Os, Cu, Ni, Co, Cd, Au, Ag, Sn, Sb, Pb, P, and As. Of those, Pt, Pd, and Os are preferred. Specific examples of compounds each of which can function as the sensitizing component are described later in the section F-3.

The sensitizing component may be a quantum dot. The quantum dot may include any appropriate material. The quantum dot may include preferably an inorganic material, more preferably an inorganic conductor material or an inorganic semiconductor material. Examples of the semiconductor material include Group II-VI, Group III-V, Group IV-VI, and Group IV semiconductors. Specific examples thereof include Si, Ge, Sn, Se, Te, B, C (including diamond), P, BN, BP, BAs, AlN, AlP, AlAs, AlSb, GaN, GaP, GaAs, GaSb, InN, InP, InAs, InSb, AlN, AlP, AlAs, AlSb, GaN, GaP, GaAs, GaSb, ZnO, ZnS, ZnSe, ZnTe, Cds, CdSe, CdSeZn, CdTe, HgS, HgSe, HgTe, Bes, BeSe, BeTe, MgS, MgSe, GeS, GeSe, GeTe, SnS, SnSe, SnTe, PbO, PbS, PbSe, PbTe, CuF, CuCl, CuBr, CuI, S₃N₄, Ge₃N₄, Al₂O₃, (Al,Ga,In)₂(S,Se,Te)₃, Al₂CO, and combinations (composites) thereof.

The sensitizing component is incorporated into the up-conversion film at a ratio of preferably from 7.00×10⁻⁹ mol to 5.00×10⁻⁴ mol, more preferably from 1.00×10⁻⁸ mol to 3.00×10⁻⁶ mol, still more preferably from 4.50×10⁻⁸ mol to 2.00×10⁻⁶ mol with respect to 1 g of the matrix.

When the content of the sensitizing component falls within such ranges, a triplet exciton can be sufficiently produced, and the efficiency with which triplet-triplet annihilation occurs can be improved.

### F-2. Light-Emitting Component

As is apparent from the mechanism described in the section A, the light-emitting component functions as follows: the light-emitting component receives the triplet-triplet energy transfer from the sensitizing component to produce an excited triplet state, and the molecules of the light-emitting component in the excited triplet state diffuse and collide with each other, or approach each other at a distance that is capable of energy transfer, to cause triplet-triplet annihilation, to thereby produce an excited singlet having a higher energy level. Various compounds each having a fused aromatic ring have each been known as the light-emitting component. Specific examples thereof include compounds each having a naphthalene structure, an anthracene structure, a pyrene structure, a perylene structure, a tetracene structure, a borondipyrromethene structure (Bodipy structure), or a diketopyrrolopyrrole structure. Specific examples of compounds each of which can function as the light-emitting component are described later in the section F-3.

The light-emitting component is incorporated into the up-conversion film at a ratio of preferably from 5.00×10⁻⁶ mol to 7.00×10⁻⁵ mol, more preferably from 6.00×10⁻⁶ mol to 6.00×10⁻⁵ mol, still more preferably from 7.00×10⁻⁶ mol to 5.00×10⁻⁵ mol with respect to 1 g of the matrix.

When the content of the light-emitting component falls within such ranges, a triplet exciton received from a sensitizing dye can sufficiently diffuse between the molecules of the light-emitting component.

A blending ratio (sensitizing component:light-emitting component) (molar ratio) between the sensitizing component and the light-emitting component is, for example, from 1:10 to 1:7,000, preferably from 1:25 to 1:3,000, more preferably from 1:30 to 1:200, still more preferably from 1:35 to 1:100. When the blending ratio falls within such ranges, a triplet exciton produced from the sensitizing component efficiently moves to a light-emitting dye, and hence deactivation between the molecules of the light-emitting dye is suppressed to the fullest extent. Thus, triplet-triplet annihilation can be satisfactorily achieved.

### F-3. Combination of Sensitizing Component and Light-Emitting Component

A preferred combination of the sensitizing component and the light-emitting component in accordance with the wavelengths of incident light and up-conversion light is as described below.

The sensitizing component that absorbs light in the wavelength region λ1 ranging from 510 nm to 550 nm is any one of the following compounds, and the light-emitting component that radiates (emits) light in the wavelength region λ2 ranging from 400 nm to 500 nm is any one of the following compounds. The combination can perform the up-conversion of green light into blue light.

### <Sensitizing Component>

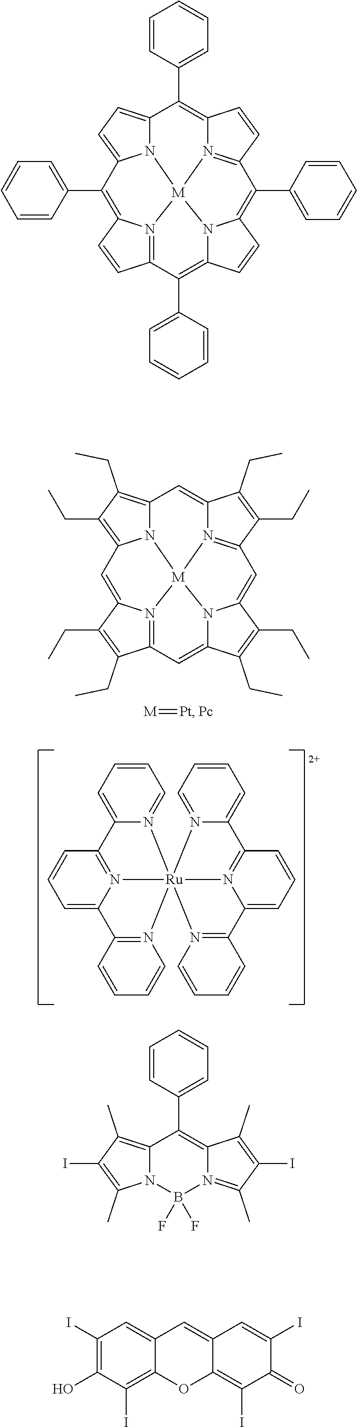

### <Light-Emitting Component>

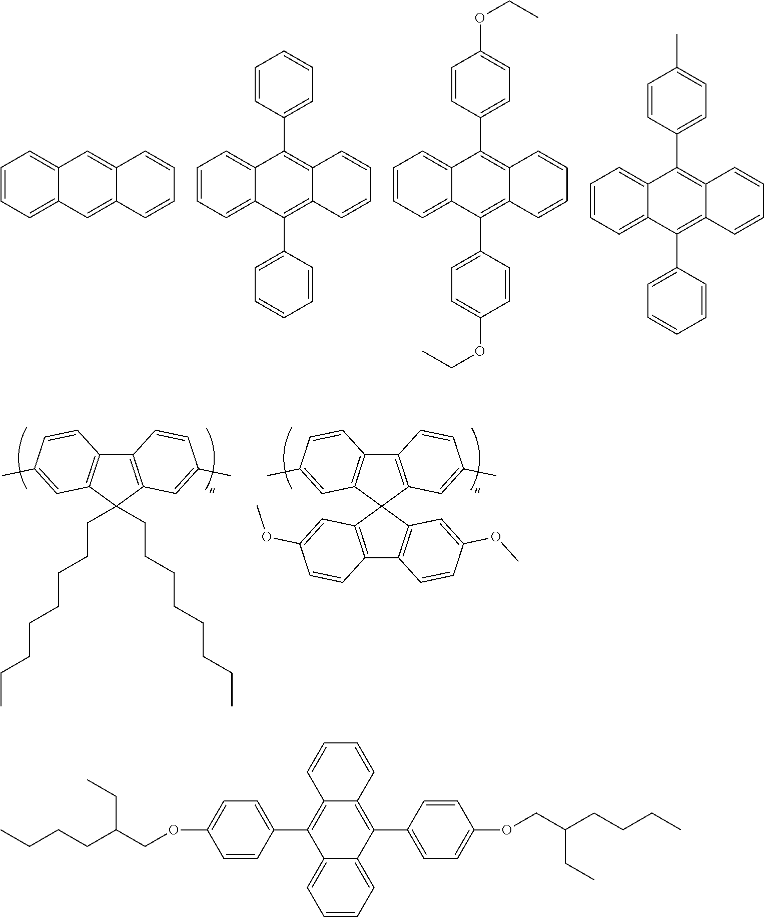

The sensitizing component that absorbs light in the wavelength region λ1 ranging from 610 nm to 650 nm is any one of the following compounds, and the light-emitting component that radiates (emits) light in the wavelength region λ2 ranging from 500 nm to 600 nm is any one of the following compounds. The combination can perform the up-conversion of red light into yellow-green light.

### <Sensitizing Component>

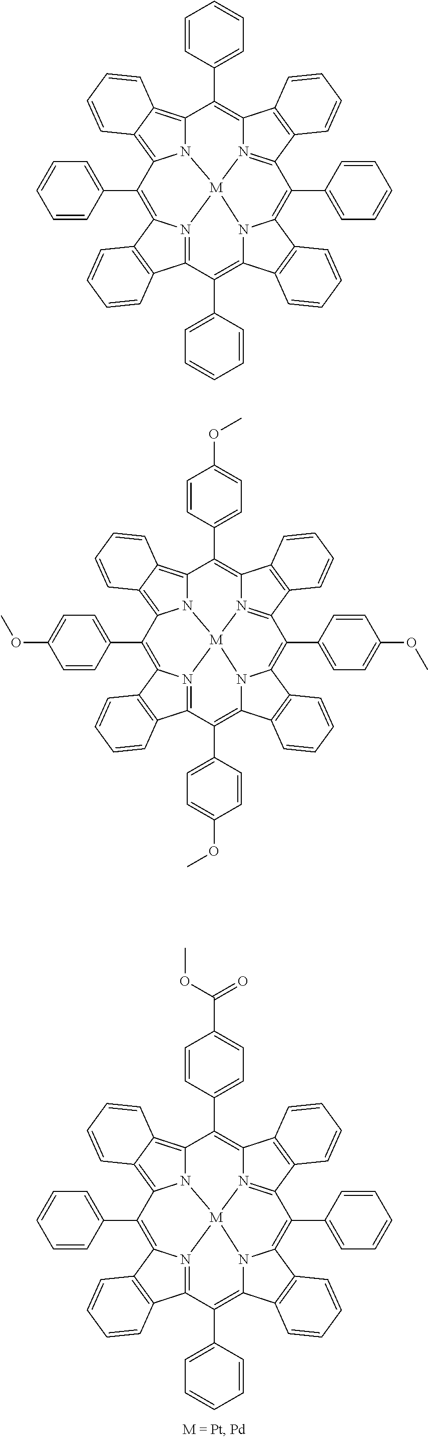

### <Light-Emitting Component>

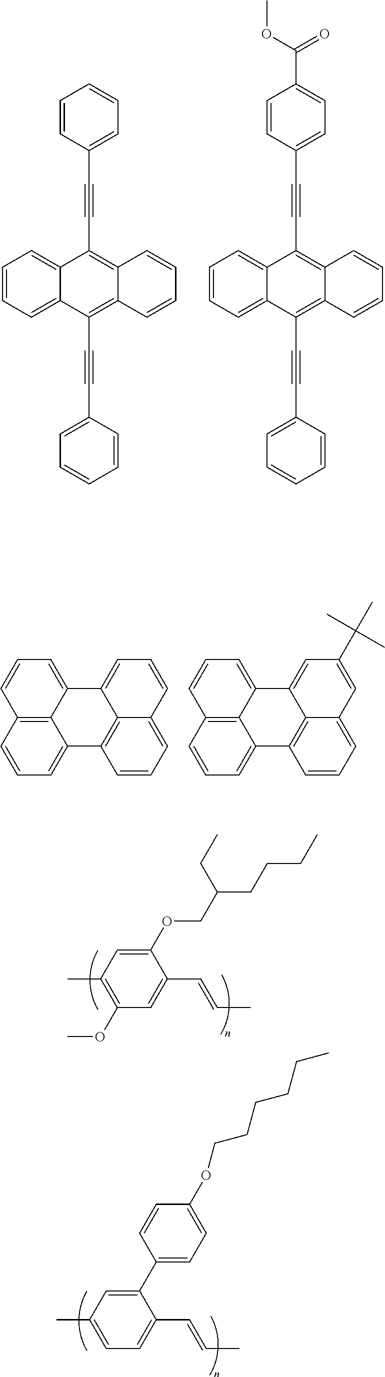

The sensitizing component that absorbs light in the wavelength region λ1 ranging from 700 nm to 810 nm is any one of the following compounds, and the light-emitting component that radiates (emits) light in the wavelength region λ2 ranging from 500 nm to 700 nm is any one of the following compounds. The combination can perform the up-conversion of near-infrared light into visible light (red light to green light).

### <Sensitizing Component>

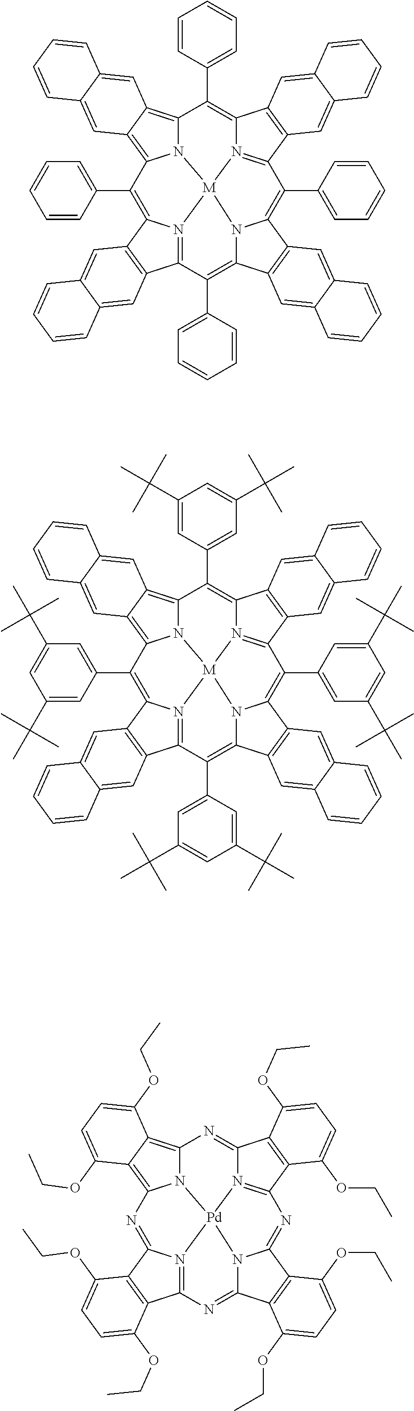

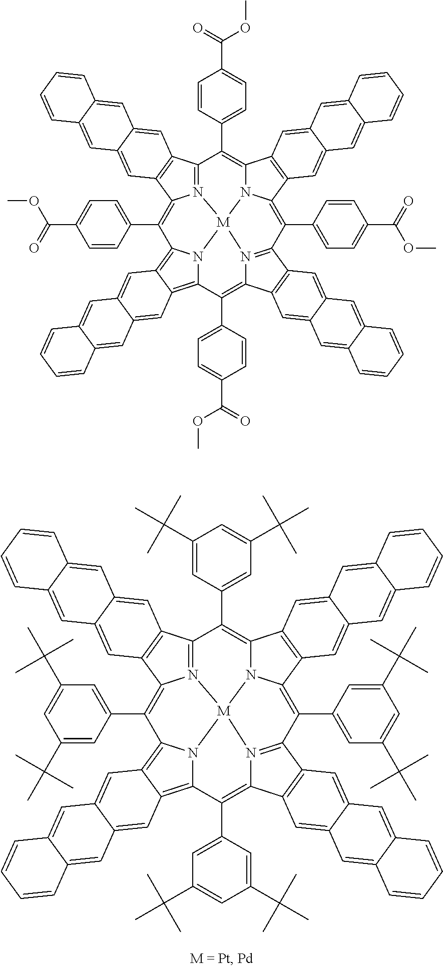

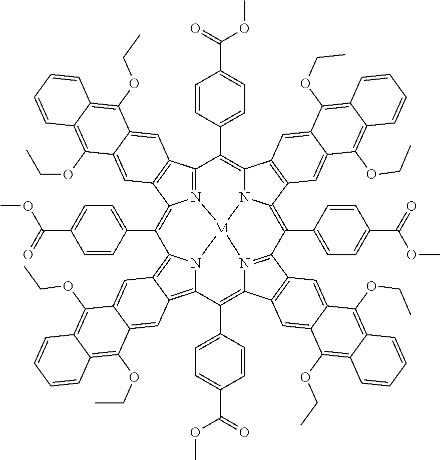

### <Light-Emitting Component>

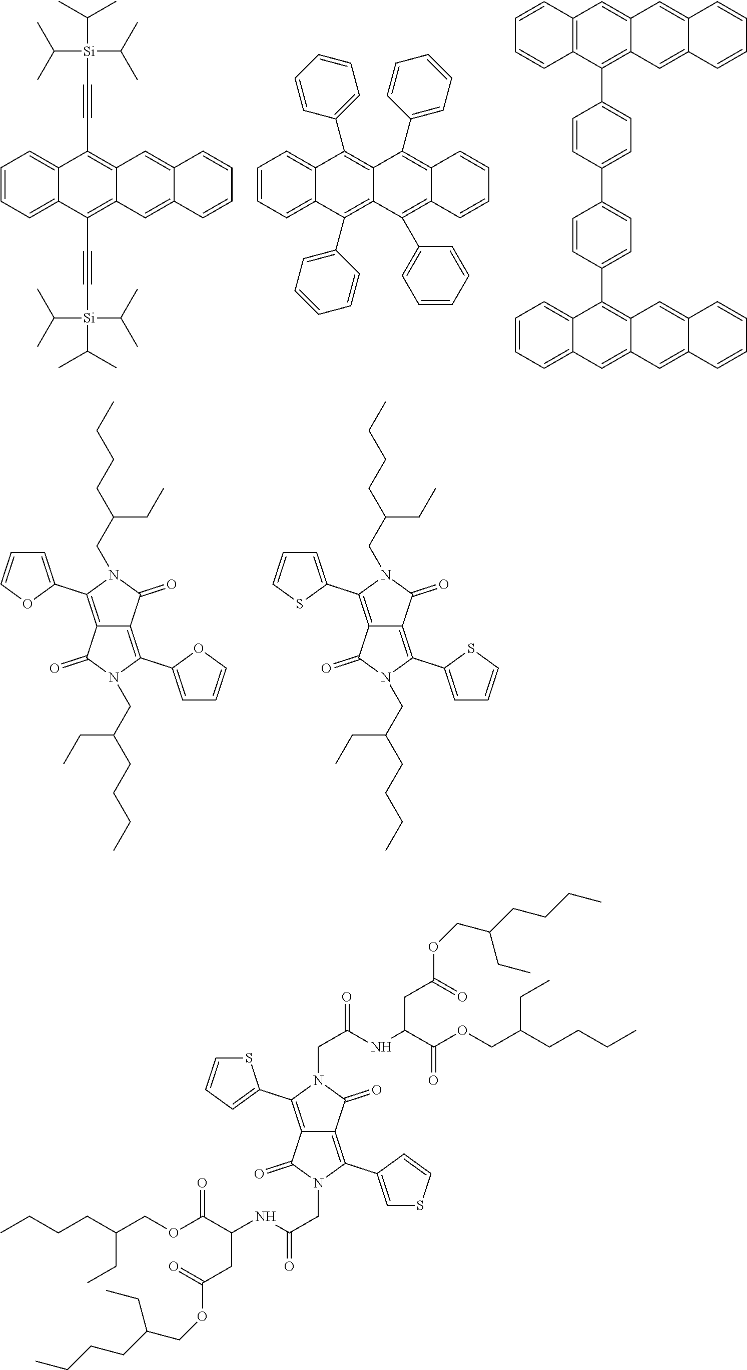

The sensitizing component that absorbs light in the wavelength region λ1 ranging from 700 nm to 730 nm is any one of the following compounds, and the light-emitting component that radiates (emits) light in the wavelength region λ2 ranging from 400 nm to 500 nm is any one of the following compounds. The combination can perform the up-conversion of near-infrared light into visible light (blue light).

### <Sensitizing Component>

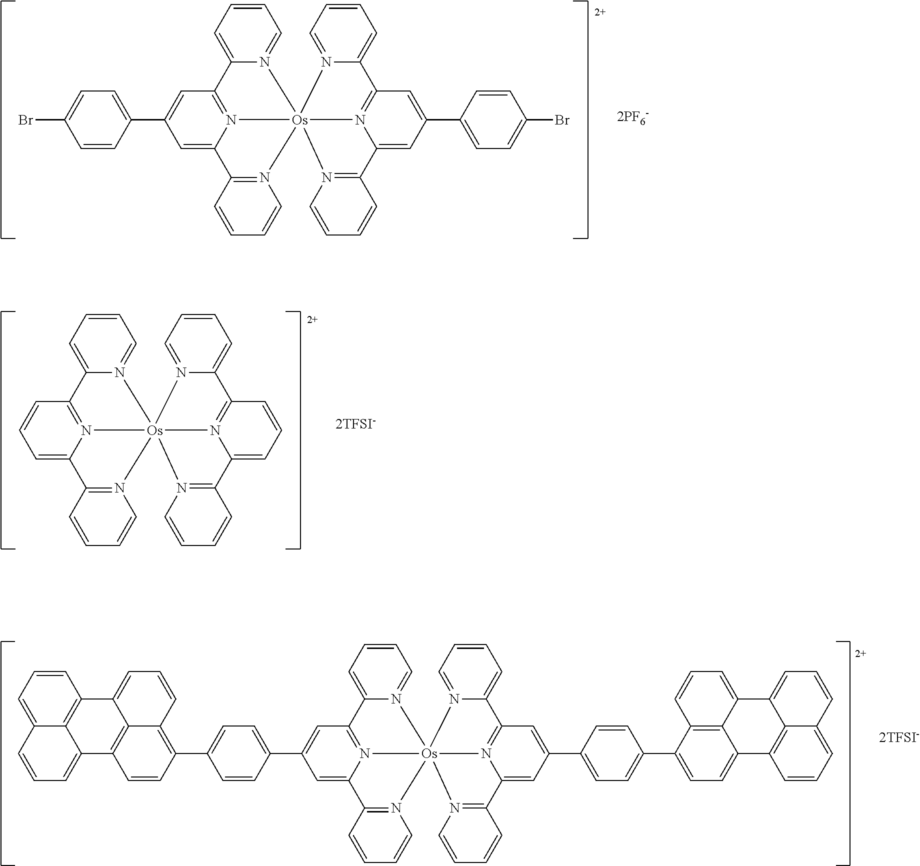

### <Light-Emitting Component>

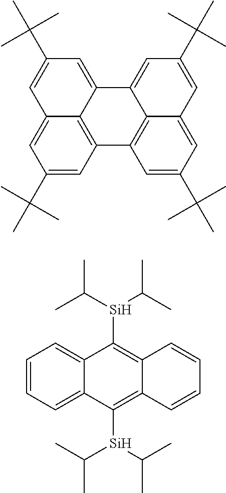

The sensitizing component that absorbs light in the wavelength region λ1 ranging from 410 nm to 500 nm is any one of the following compounds, and the light-emitting component that radiates. (emits) light in the wavelength region λ2 ranging from 300 mm to 400 nm is any one of the following compounds. The combination can perform the up-conversion of blue light into ultraviolet light.

### <Sensitizing Component>

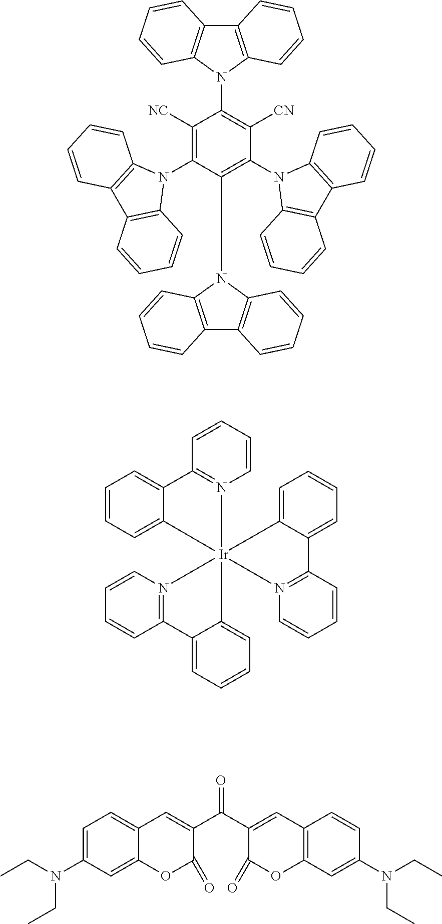

### <Light-Emitting Component>

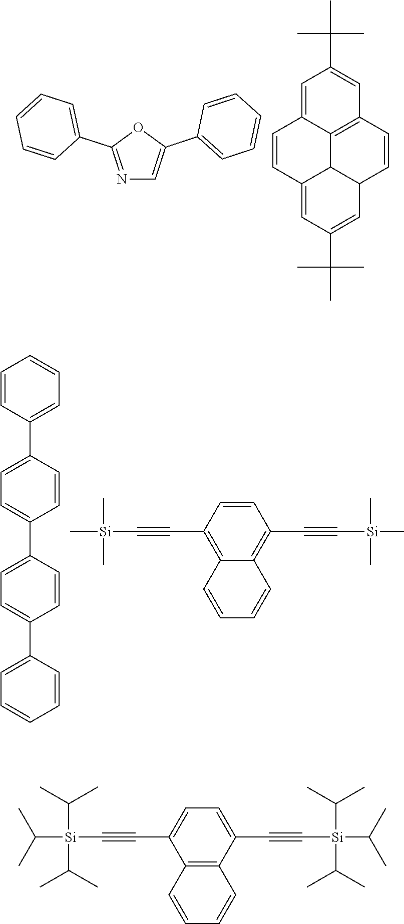

The sensitizing component that absorbs light in the wavelength region λ1 near the range of from 630 nm to 640 nm (e.g., 635 nm) is a quantum dot (CdSe or CdSe/ZnS), and the light-emitting component that radiates (emits) light in the wavelength region λ2 near the range of from 440 nm to 460 nm (e.g., 450 nm) is the following compound. The combination can perform the up-conversion of near-infrared light into visible light (blue light).

### <Light-Emitting Component>

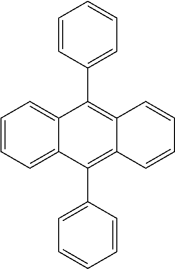 [SMILES: c1ccc(-c2c3ccccc3c(-c3ccccc3)c3ccccc23)cc1]

The sensitizing component that absorbs light in the wavelength region λ1 near the range of from 970 nm to 990 nm (e.g., 980 nm) is a quantum dot (PbSe or PbS/CdS), and the light-emitting component that radiates (emits) light in the wavelength region λ2 near the range of from 550 mm to 570 nm (e.g., 560 nm) is the following compound. The combination can perform the up-conversion of near-infrared light into visible light (green light).

### <Light-Emitting Component>

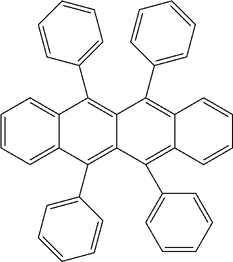 [SMILES: c1ccc(-c2c3ccccc3c(-c3ccccc3)c3c(-c4ccccc4)c4ccccc4c(-c4ccccc4)c23)cc1]

### G. Surfactant

The photon up-conversion film may further include a surfactant. When the photon up-conversion film includes a surfactant, the dispersibility of the color-forming portion in the matrix can be improved. Examples of the surfactant include a cationic surfactant such as hexadecyltrimethylammonium bromide (CTAB), an anionic surfactant, and a nonionic surfactant. Of those, CTAB is a preferred example.

The addition ratio of the surfactant is, for example, from 0 parts by weight to 200 parts by weight, preferably from 1 part by weight to 50 parts by weight, with respect to 100 parts by weight of the medium.

### H. Method of Producing Photon Up-Conversion Film

In one embodiment, a method of producing a photon up-conversion film includes: preparing an emulsion from an aqueous solution containing a water-soluble resin, and a solution or dispersion of the sensitizing component and the light-emitting component (hereinafter sometimes collectively referred to as “dye solution or the like”); applying the emulsion to a substrate to form a coating film; and drying the coating film. The respective steps are specifically described below.

### <Preparation of Emulsion>

In the preparation of the emulsion, a dye solution or the like corresponding to a desired up-conversion film is first prepared.

When an up-conversion film (UC film) is produced by using a medium having fluidity at 298 K (24.85° C.), an organic solvent is added to the medium described in the above-mentioned section C (specifically, the normal-temperature liquid crystal compound and/or the solvent) as required, and then, the sensitizing component and the light-emitting component described in the above-mentioned section F are added thereto, and the mixture is stirred.

When the organic solvent is added to the medium, the solubility of each of the sensitizing component and the light-emitting component can be improved. In particular, when the fluid medium is the normal-temperature liquid crystal compound, it is preferred that the organic solvent be added to the normal-temperature liquid crystal compound.

For example, a solvent having volatility may be used as the organic solvent. Specific examples of such solvent include: ethers such as tetrahydrofuran; halogenated hydrocarbons, such as chloroform and dichloromethane; and toluene. The organic solvents may be used alone or in combination thereof. Of such organic solvents, ethers are preferred examples, and tetrahydrofuran is a more preferred example.

The addition ratio of the organic solvent is, for example, from 0 parts by weight to 200 parts by weight, preferably from 80 parts by weight to 120 parts by weight, with respect to 100 parts by weight of the fluid medium.

The above-mentioned additive may also be added to the medium. The additive may be added to the medium with the organic solvent, or the additive alone may be added to the medium. When the additive is added to the medium, the viscosity, refractive index, and/or phase transition temperature of the medium can be appropriately adjusted.

The addition ratio of the additive is, for example, from 0 parts by weight to 200 parts by weight, preferably from 5 parts by weight to 100 parts by weight, with respect to 100 parts by weight of the medium.

In addition, a plurality of kinds of liquid crystal compounds, organic solvents, and other additives may be mixed at any appropriate mixing ratio.

When an up-conversion film (UC film containing a high-temperature liquid crystal compound) is produced by using a high-temperature liquid crystal compound, after the high-temperature liquid crystal compound described in the above-mentioned section C is heated to be brought into a liquid crystal state, the above-mentioned organic solvent is added to the compound as required, the sensitizing component and the light-emitting component described in the above-mentioned section F are added thereto, and the mixture is stirred.

The heating temperature of the high-temperature liquid crystal compound may be optionally and appropriately adjusted in accordance with the high-temperature liquid crystal compound. The heating temperature of the high-temperature liquid crystal compound is, for example, equal to or more than a phase transition temperature T_{K-N} between crystal and liquid crystal, and equal to or less than a phase transition temperature T_{N-I} between liquid crystal and isotropic liquid.

When the organic solvent is added to the high-temperature liquid crystal compound in a liquid crystal state, the solubility of each of the sensitizing component and the light-emitting component can be improved. The addition ratio of the organic solvent is, for example, from 0 parts by weight to 200 parts by weight, preferably from 80 parts by weight to 120 parts by weight, with respect to 100 parts by weight of the high-temperature liquid crystal compound.

Accordingly, a dye solution or the like suitable for the production of the UC film having a relaxation time of less than 210 ms is prepared. The dye solution or the like is typically a medium in which the sensitizing component and the light-emitting component are dissolved and/or dispersed.

The concentration of the sensitizing component in the dye solution or the like may be, for example, from 0.001 mM to 1 mM, and the concentration of the light-emitting component therein may be, for example, from 1 mM to 50 mM.

In addition, the aqueous solution of the water-soluble resin described in the above-mentioned section E is prepared. The concentration of the aqueous solution may be, for example, from 3 wt % to 20 wt %, or may be, for example, from 5 wt % to 10 wt %.

Next, the aqueous solution of the water-soluble resin, and the dye solution or the like are mixed with each other so that the blending amounts of the sensitizing component and the light-emitting component with respect to the water-soluble resin (matrix) may fall within the desired ranges described in the above-mentioned section F. More specifically, the aqueous solution of the water-soluble resin, and the dye solution or the like are mixed with each other, and the mixed liquid is emulsified with a homogenizer. At this time, the above-mentioned surfactant is added thereto as required. As a result, droplets of the dye solution or the like can be suitably dispersed in the aqueous solution of the water-soluble resin to prepare an emulsion. The resultant emulsion may be defoamed as required. In addition, a volatile component (e.g., an organic solvent) in the resultant emulsion may be evaporated under reduced pressure. Thus, the concentrations of the sensitizing component and the light-emitting component in the emulsion can be improved. The volume fraction of emulsion particles is, for example, from 5% to 60%. The average particle diameter of the emulsion particles is, for example, from 0.1 μm to 10 μm. When the volume fraction and/or average particle diameter of the emulsion particles falls within such ranges, a color-forming portion having a desired size can be formed as a dispersion phase in the up-conversion film.

### <Formation and Drying of Coating Film>

Next, the emulsion obtained in the foregoing is applied to the substrate to form the coating film. The substrate is typically, for example, a resin sheet or glass. Any appropriate resin may be used as a resin for forming the resin sheet. Specific examples thereof include transparent resins including a polyimide-based resin, a cellulose-based resin such as triacetyl cellulose (TAC), a polyester-based resin such as polyethylene terephthalate (PET), a polyvinyl alcohol-based resin, a polycarbonate-based resin, a polyamide-based resin, a polyether sulfone-based resin, a polysulfone-based resin, a polystyrene-based resin, a polynorbornene-based resin, a polyolefin-based resin, a (meth)acrylic resin, and an acetate-based resin. The examples also include thermosetting resins or UV-curable resins, such as (meth)acrylic, urethane-based, (meth)acrylic urethane-based, epoxy-based, and silicone-based resins. The examples further include glassy polymers such as a siloxane-based polymer.

Any appropriate method may be used as a method for the application. Specific examples thereof include a roll coating method, a spin coating method, a wire bar coating method, a dip coating method, a die coating method, a curtain coating method, a spray coating method, and a knife coating method (e.g., a comma coating method). In addition, the coating film may be formed by using a drum film-forming machine. In this case, the film-forming roll (drying roll) of the drum film-forming machine can function as the substrate. The film-forming roll (drying roll) is formed from, for example, a metal, such as nickel, chromium, copper, iron, or stainless steel. The temperature of the emulsion at the time of the application may be, for example, from 10° C. to 60° C. The thickness of the coating film is adjusted so that the thickness of the up-conversion film to be obtained may fall within the desired range (e.g., from 5 μm to 200 μm) described in the above-mentioned section B. The thickness of the coating film may be, for example, from 100 μm to 1,000 μm.

Next, the coating film is dried. The drying is performed with any appropriate means (e.g., an oven). A drying temperature may be, for example, from 60° C. to 90° C., and a drying time may be, for example, from 20 minutes to 60 minutes. The drying may provide a dried coating film having a thickness substantially identical to that of the up-conversion film to be obtained. Typically, the dried coating film may be naturally cooled to room temperature (23° C.).

Thus, the up-conversion film is prepared. The up-conversion film may be peeled from the substrate, or may be used as a laminate with the substrate without peeling of the up-conversion film from the substrate.

### I. Application of Photon Up-Conversion Film

The up-conversion film described in the above-mentioned sections A to H can be applied to any appropriate industrial products. Examples of the industrial products include a laminate and an energy conversion device. Accordingly, one embodiment of the present invention also encompasses a laminate and an energy conversion device each using such up-conversion film.

The laminate includes the up-conversion film described in the above-mentioned sections A to H and any appropriate film (layer) to be laminated on the up-conversion film.

The energy conversion device includes at least the up-conversion film described in the above-mentioned sections A to H and may further have any appropriate configuration in addition to the up-conversion film.

### I-1. Laminate

The laminate may include a first protective layer and a second protective layer, which are arranged on a light incident surface and a light emission surface of the up-conversion film, respectively. Each of the first protective layer and the second protective layer may be omitted in accordance with purposes. In addition, any appropriate optical member may be arranged between the up-conversion film and the first protective layer and/or between the up-conversion film and the second protective layer as long as the effects of the present invention are obtained.

In one embodiment, the laminate has a configuration in which at least the first protective layer to the second protective layer are integrated with each other. Herein, the expression “the first protective layer to the second protective layer are integrated with each other” means that members between the first protective layer and the second protective layer for forming the laminate are linked into one as a whole. The integration may be carried out by, for example, bonding members adjacent to each other through an adhesion layer, such as a pressure-sensitive adhesive layer or an adhesive layer. In addition, a layer having a different function, such as an overcoat, may be directly applied to the photon up-conversion film. It is preferred that the first protective layer, the up-conversion film, the second protective layer, and any appropriate protective layer are integrated with each other through the adhesion layer.

The overcoat is formed from any appropriate material. Examples of a material for the overcoat include an acrylic resin and an epoxy-based resin.

In another embodiment, the laminate has a configuration in which the first protective layer and the second protective layer are not integrated with each other. Herein, the expression “the first protective layer and the second protective layer are not integrated with each other” means that at least one of members between the first protective layer and the second protective layer for forming the laminate is merely laminated on one or both of adjacent members. For example, the laminate in the embodiment may have a configuration in which the first protective layer, the up-conversion film, and the second protective layer are arranged in the stated order without the adhesion layer. Moreover, for example, the laminate in the embodiment may have a configuration in which the first protective layer to the up-conversion film are integrated with each other through the adhesion layer, and the second protective layer is arranged on a light emission side of the integrated laminate without the adhesion layer. In addition, for example, the laminate in the embodiment may have a configuration in which the up-conversion film to the second protective layer are integrated with each other through the adhesion layer, and the first protective layer is arranged on a light incident side of the integrated laminate without the adhesion layer.

### I-2. Protective Layer

Each of the first protective layer and the second protective layer is formed from any appropriate film usable as the protective layer of the up-conversion film. Specific examples of a material serving as a main component of the film include transparent resins including a cellulose-based resin such as triacetyl cellulose (TAC), and polyester-based, polyvinyl alcohol-based, polycarbonate-based, polyamide-based, polyimide-based, polyether sulfone-based, polysulfone-based, polystyrene-based, polynorbornene-based, polyolefin-based, (meth)acrylic, and acetate-based resins. The examples also include: thermosetting resins or UV-curable resins, such as (meth)acrylic, urethane-based, (meth)acrylic urethane-based, epoxy-based, and silicone-based resins; and inorganic materials, such as glass and silica. The examples further include glassy polymers such as a siloxane-based polymer. In addition, a polymer film described in JP 2001-343529 A (WO 01/37007 A1) may be used. For example, a resin composition containing a thermoplastic resin having a substituted or unsubstituted imide group on a side chain and a thermoplastic resin having a substituted or unsubstituted phenyl group and a nitrile group on side chains may be used as a material for the film. The resin composition is, for example, a resin composition containing an alternating copolymer of isobutene and N-methyl maleimide, and an acrylonitrile-styrene copolymer. The polymer film may be, for example, an extrusion molded product of the above-mentioned resin composition.

### J. Photon Up-Conversion Body

In the above-mentioned sections A to H, the up-conversion film has been described in detail. However, a form is not limited to a film form as long as up-conversion in a solid state is possible.

A photon up-conversion body is in a solid state at normal temperature (23° C.) and normal pressure (0.1 MPa). Examples of the form of the photon up-conversion body include crystal, powder, and gel.

The photon up-conversion body is described similarly to the up-conversion film except for a solution state. Accordingly, the description of the photon up-conversion body is omitted.

### EXAMPLES

The present invention is specifically described below by way of Examples. However, the present invention is not limited to these Examples. In Examples, “part(s)” and “%” are by weight unless otherwise specified.

### Example 1

### 1. Preparation of DMP Solution of Sensitizing Component and Light-Emitting Component

Platinum octaethylporphyrin (PtOEP: the following chemical formula) serving as a sensitizing component and 9,10-diphenylanthracene (DPA: the following chemical formula) serving as a light-emitting component were dissolved in dimethyl phthalate (DMP) in a glove box to prepare a DMP solution of the sensitizing component and the light-emitting component. The concentration of the sensitizing component in the solution was 2.39×10⁻⁷ M, and the concentration of the light-emitting component therein was 4.78×10⁻⁵ M. That is, the molar ratio of the sensitizing component to the light-emitting component was 1:200. The prepared solution was stored by being hermetically sealed in a vial until an emulsifying step.

### <Sensitizing Component>

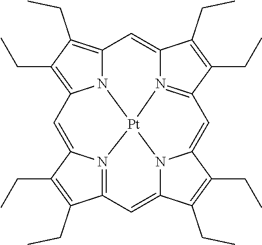

### <Light-Emitting Component>

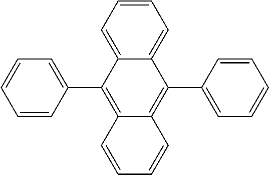 [SMILES: c1ccc(-c2c3ccccc3c(-c3ccccc3)c3ccccc23)cc1]

### 2. Preparation of Emulsion

0.4 ml of the solution obtained in the foregoing was added to 5 g of an aqueous solution (9 wt %) of polyvinyl alcohol (PVA). While the solution was injected with a tube having an inner diameter of 0.75 mm, the mixture was stirred (17,500 rpm) with a homogenizer until its entirety was emulsified. An argon gas was blown to the resultant emulsified liquid for about 2 minutes, and the emulsified liquid was stirred with a stirring machine (THINKY) in a mixing mode (2,000 rpm) for 5 minutes and in a defoaming mode (2,200 rpm) for 5 minutes. Thus, an emulsion was prepared. A product having a polymerization degree of 1,700 and a saponification degree of 99% was used as the PVA.

### 3. Formation of Up-Conversion Film

The emulsion obtained in the foregoing was applied to a polyimide film (substrate) with an applicator so as to have an application thickness of 700 μm. The laminate of the coating film and the polyimide film was dried in a thermostat. A drying temperature was 80° C., and a drying time was 30 minutes. After the drying, the laminate was naturally cooled to room temperature (23° C.). Finally, the dried coating film was peeled from the polyimide film. Thus, an up-conversion film (thickness: 63 μm) was obtained. A process after the preparation of the emulsion was performed in air and in a dark place (under an environment including only light for a darkroom).

### Example 2

An up-conversion film was obtained in the same manner as in Example 1 except that the DMP solution of the sensitizing component and the light-emitting component was changed to a crystal solution of the sensitizing component and the light-emitting component prepared as described below.

100 Parts by weight of tetrahydrofuran (THE) was added to 100 parts by weight of 4-cyano-4′-pentylbiphenyl (5CB) at room temperature (23° C.), and the contents were stirred and mixed to prepare a liquid crystal solvent. Next, PtOEP serving as the sensitizing component and DPA serving as the light-emitting component were dissolved in the liquid crystal solvent to prepare the liquid crystal solution of the sensitizing component and the light-emitting component.

### Example 3

An up-conversion film was obtained in the same manner as in Example 2 except that 5CB was changed to 4-cyano-4′-heptylbiphenyl (7CB).

### Example 4

An up-conversion film was obtained in the same manner as in Example 1 except that the DMP solution of the sensitizing component and the light-emitting component was changed to a crystal solution of the sensitizing component and the light-emitting component prepared as described below.

100 Parts by weight of 4-cyano-4′-pentyloxybiphenyl (50CB) was heated to 60° C. in a hot water bath to be brought into a liquid crystal state, 100 parts by weight of tetrahydrofuran was added thereto, and the contents were stirred and mixed to prepare a liquid crystal solvent. Next, PtOEP serving as the sensitizing component and DPA serving as the light-emitting component were dissolved in the liquid crystal solvent to prepare the liquid crystal solution of the sensitizing component and the light-emitting component.

### Example 5

An up-conversion film was obtained in the same manner as in Example 2 except that the aqueous solution of PVA was changed to an aqueous solution (9 wt %) of polyethylene oxide (PEO) (molecular weight: 200,000).

### Example 6

An up-conversion film was obtained in the same manner as in Example 2 except that the sensitizing component was changed to palladium meso-tetraphenyl-tetraanthraporphyrin (PdTPTAP: the following chemical formula) and the light-emitting component was changed to rubrene (the following chemical formula). The concentration of PdTPTAP in the solution was set to 0.554 mM, and the concentration of rubrene therein was set to 20 mM. That is, the molar ratio of the sensitizing component to the light-emitting component was set to 1:36.

### <Sensitizing Component>

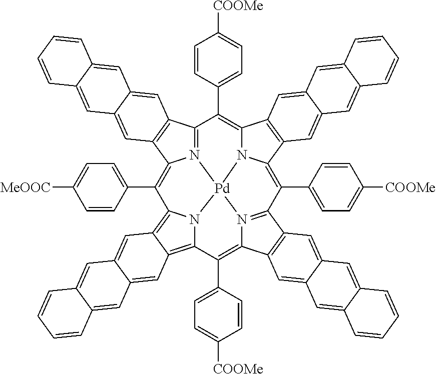

### <Light-Emitting Component>

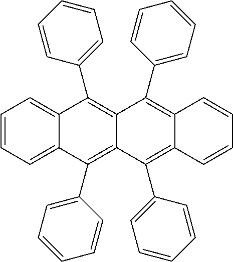 [SMILES: c1ccc(-c2c3ccccc3c(-c3ccccc3)c3c(-c4ccccc4)c4ccccc4c(-c4ccccc4)c23)cc1]

### Example 7

PtOEP serving as a sensitizing component, DPA serving as a light-emitting component, 100 parts by weight of tetrahydrofuran (THF), and 5 parts by weight of MCT oil were added to 100 parts by weight of 4-cyano-4′-pentylbiphenyl (5CB) at room temperature (23° C.), and the contents were stirred and mixed to prepare a liquid crystal solvent. The above-mentioned liquid crystal solution was added to 1 mL of a 1 wt % aqueous solution of CTAB (surfactant aqueous solution), and the contents were stirred with an ultrasonic homogenizer to prepare an emulsion solution. 1.8 ml of the solution obtained in the foregoing was added to 5 g of an aqueous solution (9 wt %) of polyvinyl alcohol (PVA). A subsequent procedure was performed in the same manner as in Example 1 to provide an up-conversion film.

### Example 8

An up-conversion film was obtained in the same manner as in Example 7 except that 5CB was changed to 4-cyano-4′-pentylphenylcyclohexane (PCH5CN).

### Example 9

An up-conversion film was obtained in the same manner as in Example 7 except that 5CB was changed to 4-cyano-4′-pentyloxybiphenyl (50CB).

### Example 10

An up-conversion film was obtained in the same manner as in Example 7 except that 5 parts by weight of the MCT oil was changed to 5 parts by weight of hexadecane.

### Example 11

An up-conversion film was obtained in the same manner as in Example 7 except that 5 parts by weight of the MCT oil was changed to 5 parts by weight of liquid paraffin.

### Example 12

An up-conversion film was obtained in the same manner as in Example 7 except that the sensitizing component was changed to palladium meso-tetraphenyl-tetraanthraporphyrin (PdTPTAP: the above-mentioned chemical formula) and the light-emitting component was changed to rubrene (the above-mentioned chemical formula). The concentrations of the respective components were the same as those in Example 6.

### Example 13

An up-conversion film was obtained in the same manner as in Example 2 except that 5CB was changed to a mixed liquid crystal (ZLI1052) of 4-pentylphenyl 4-methoxybenzoate (PE105) and 4-pentylphenyl 4-hexyloxybenzoate (PE605).

### Example 14

An up-conversion film was obtained in the same manner as in Example 2 except that 5CB was changed to a mixed liquid crystal (ZLI1132) of 4-cyano-4′-propylphenylcyclohexane (PCH-3CN), 4-cyano-4′-pentylphenylcyclohexane (PCH-5CN), 4-cyano-4′-phenylcyclohexane (PCH-7CN), and 4-cyano-4′-pentylbiphenylcyclohexane (BCH-5CN).

### Example 15

An up-conversion film was obtained in the same manner as in Example 2 except that 5CB was changed to a mixed liquid crystal (ZLI1083) of 4-cyano-4′-propylphenylcyclohexane (PCH-3CN), 4-cyano-4′-pentylphenylcyclohexane (PCH-5CN), and 4-cyano-4′-phenylcyclohexane (PCH-7CN).

### Example 16

An up-conversion film was obtained in the same manner as in Example 2 except that 5CB was changed to a mixed liquid crystal (E7) of 4-cyano-4′-pentylbiphenyl (5CB), 4-cyano-4′-heptylbiphenyl (7CB), 4-cyano-4′-n-octyloxybiphenyl (80CB), and 4-cyano-4′-pentyl-p-terphenyl (5CT).

### Example 17

An up-conversion film was obtained in the same manner as in Example 2 except that 5CB was changed to a mixed liquid crystal (ES) of 4-cyano-4′-pentylbiphenyl (5CB), 4-cyano-4′-heptylbiphenyl (7CB), 4-cyano-4′-pentyloxybiphenyl (50CB), 4-cyano-4′-n-octyloxybiphenyl (80CB), and 4-cyano-4′-pentyl-p-terphenyl (5CT).

### Example 18

An up-conversion film was obtained in the same manner as in Example 1 except that DMP was changed to tricaprin.

### Example 19

A liquid crystal solvent was prepared by the same procedure as in Example 4. In addition, glass was placed on a hot plate heated to 80° C., and the liquid crystal solvent was arranged on the glass so that THE was volatilized. As a result, an up-conversion body in a crystalline form was obtained.

### Comparative Example 1

An up-conversion film (thickness: 60 μm) was obtained in the same manner as in Example 1 except that DMP was changed to toluene.

### Comparative Example 2

An up-conversion film was obtained in the same manner as in Example 6 except that the crystal solvent was changed to toluene.

### <Measurement of Relaxation Time by Time-Domain Nuclear Magnetic Resonance (TD-NMR)>

The up-conversion film or the up-conversion body obtained in each of Examples described above was cut into a strip shape to provide a sample. The short-side dimension of the sample was 1.5 cm, and the long-side dimension of the sample was from 7 cm to 12 cm. About two to four pieces of the sample were put into a sample tube.

Next, the sample in the sample tube was measured at 298 K by a spin-echo method through use of TD-NMR (pulse NMR). Analysis was performed from the free induction decay curve of the resultant ¹H nuclear spin-spin relaxation by nonlinear least-squares to calculate a T2 relaxation time. The results are shown in Table 1 to Table 3.

As measurement conditions, a recycle delay was set to 10 s, the number of scans was set to 8, and the number of measurement points was set to 50. Measurement was performed in such a range that the relative signal intensity of a final plotted point when the signal intensity of a first plotted point was standardized as 1 was 0.001 or more and 0.1 or less, and the relaxation time was analyzed.

Fitting of an exponential model with a Weibull coefficient of 1 was conducted through use of analysis software “TDNMR-A Version 6.9 Rev 2.0” manufactured by Bruker Corporation in accordance with its product manual. For the sample into which a Weibull coefficient of 1 was not fit, an optimal value within the range of from 1 to 2 was used.

The measurement conditions are described below.
Apparatus: TD-NMR (the minispec mq20), manufactured by Bruker
Corporation
Detection nuclear species: ¹H
Measurement temperature: 298 K
Measurement method: spin-echo method
Analysis method: nonlinear least-squares
Scan: 8
Recycle delay: 10 sec
First 90° to 180° pulse separation time: 0.0082
Final 90° to 180° pulse separation time: adjusted to the above-mentioned conditions
Number of data points for fitting: 50

When the resultant relaxation times were detected for two or more components, an average value was calculated from relaxation times determined by multiplying the resultant relaxation times by proton ratios and adding the values for all the components. This average value was adopted as a relaxation time.

### <Measurement of Absolute Quantum Yield>

The absolute quantum yield (based on 100%) of up-conversion emission of the up-conversion film or the up-conversion body (hereinafter referred to as “sample”) obtained in each of Examples and Comparative Examples described above was measured with an absolute quantum yield measurement system Quantaurus-QY Plus C11347-02 (manufactured by Hamamatsu Photonics K.K., detection wavelength: from 400 nm to 1,100 nm).

In the measurement of the absolute quantum yield, a diode laser (808 nm, 200 mW, 532 nm, 75 mW, 460 nm, 500 mw, RGB photonics) was used as an excitation source by adjusting the light intensity through use of a laser output and an ND filter. The amounts of light at 808 nm, 532 nm, and 460 nm were adjusted to 27,000 mW/cm², 31,000 mW/cm², and 31,000 mW/cm², respectively, so that the sample was irradiated with light, and the measurement was performed.

The measured absolute quantum yields are shown in Table 1 to Table 3.

### <Measurement of Transmittance>

The transmittance of the up-conversion film or the up-conversion body obtained in each of Examples and Comparative Examples described above was measured with an ultraviolet-visible-near infrared spectrophotometer UH4150 (manufactured by Hitachi High-Tech Corporation). In the measurement of the transmittance, the sample was directly installed in front of an integrating sphere, and a total light transmittance was measured at intervals of 1 nm in a wavelength range of 400 nm or more and 800 nm or less. In this measurement, the average value of the obtained transmittances at from 400 nm to 800 nm was used as an average transmittance.

The measured average transmittances are shown in Table 1 to Table 3.

TABLE 1

| | | | | Color-forming portion solvent (medium) | | | |
|---|---|---|---|---|---|---|---|
| | | Light- | | Monomolecular | | | |
| | Sensitizing | emitting | | Liquid crystal | | | |
| No. | component | component | Matrix | compound | Compound name | Manufacturer | Solvent |
| Example 1 | PtOEP | DPA | PVA | DMP | — | — | Dimethyl |
| | | | | | | | phthalate |
| Example 2 | PtOEP | DPA | PVA | 5CB | 4-cyano-4′- | Tokyo | THF |
| | | | | | pentylbiphenyl | Chemical | |
| | | | | | | Industry | |
| | | | | | | Co., Ltd. | |
| Example 3 | PtOEP | DPA | PVA | 7CB | 4-cyano-4′- | Tokyo | THF |
| | | | | | heptylbiphenyl | Chemical | |
| | | | | | | Industry | |
| | | | | | | Co., Ltd. | |
| Example 4 | PtOEP | DPA | PVA | 5OCB | 4-cyano-4′- | LCC Co, | THF |
| | | | | | pentyloxybiphenyl | Ltd. | |
| Example 5 | PtOEP | DPA | PEO | 5CB | 4-cyano-4′- | Tokyo | THF |
| | | | | | pentylbiphenyl | Chemical | |
| | | | | | | Industry | |
| | | | | | | Co., Ltd. | |
| Example 6 | PdTPTAP | Rubrene | PVA | 5CB | 4-cyano-4′- | Tokyo | THF |
| | | | | | pentylbiphenyl | Chemical | |
| | | | | | | Industry | |
| | | | | | | Co., Ltd. | |
| Comparative | PtOEP | DPA | PVA | — | — | — | Toluene |
| Example 1 | | | | | | | |
| Comparative | PdTPTAP | Rubrene | PVA | — | — | — | Toluene |
| Example 2 | | | | | | | |

| | | | Temperature | | | | | | |
|---|---|---|---|---|---|---|---|---|---|
| | | | (medium | | | | | | |
| | | | alone) at | | | | | | |
| | | | remaining | | | | | | |
| | | | amount of | T2 | | | | Absolute | |
| | Viscosity | Bolling | 95% in | relaxation | | Excitation | Emission | quantum | Average |
| | (23° C.) | point | TG/DTA | time by | | wavelength | wavelength | yield | transmittance |
| No. | [mPa · s] | [° C.] | [° C.] | TD-NMR | | [nm] | [nm] | [%] | [%] |
| Example 1 | 4.5 | 283 | 149.37 | 89 | ms | 532 | 433 | 6.2 | 41.1 |
| Example 2 | 32 | 215 | 228.94 | 57 | μs | 532 | 433 | 31.6 | 35.6 |
| Example 3 | 56 | 211 | 243.35 | 56 | μs | 532 | 433 | 35.4 | 45.3 |
| Example 4 | N.D. | 418 | 245.37 | 47 | μs | 532 | 433 | 30.7 | 34.8 |
| Example 5 | 32 | 215 | 228.94 | 382 | μs | 532 | 433 | 4.6 | 26.5 |
| Example 6 | 32 | 215 | 228.94 | 57 | μs | 808 | 560 | 4.4 | 33.2 |
| Comparative | 0.6 | 111 | — | 210 | ms | 532 | 433 | 2.3 | 36.8 |
| Example 1 | | | | | | | | | |
| Comparative | 0.6 | 111 | — | 210 | ms | 808 | 560 | 1.8 | 29.7 |
| Example 2 | | | | | | | | | |

TABLE 2

| | | | | Color-forming portion solvent (medium) | | | | |
|---|---|---|---|---|---|---|---|---|
| | | Light- | | Monomolecular | | | | |
| | Sensitizing | emitting | | liquid crystal | Compound | | | |
| No. | component | component | Matrix | compound | name | Manufacturer | Solvent | Additive |
| Example 7 | PtOEP | DPA | PVA | 5CB | 4-cyano-4′- | Tokyo | THF | MCT oil |
| | | | | | pentylbiphenyl | Chemical | | |
| | | | | | | Industry | | |
| | | | | | | Co., Ltd. | | |
| Example 8 | PtOEP | DPA | PVA | PCH5CB | 4-cyano-4′- | Tokyo | THF | MCT oil |
| | | | | | pentylphenyl- | Chemical | | |
| | | | | | cyclohexane | Industry | | |
| | | | | | | Co., Ltd. | | |
| Example 9 | PtOEP | DPA | PVA | 5OCB | 4-cyano-4′- | LCC Co, | THF | MCT oil |
| | | | | | pentyloxy- | Ltd. | | |
| | | | | | biphenyl | | | |
| Example 10 | PtOEP | DPA | PVA | 5CB | 4-cyano-4′- | Tokyo | THF | Bexadecane |
| | | | | | pentyl- | Chemical | | |
| | | | | | biphenyl | Industry | | |
| | | | | | | Co., Ltd. | | |
| Example 11 | PtOEP | DPA | PVA | 5CB | 4-cyano-4′- | Tokyo | THF | Liquid |
| | | | | | pentyl- | Chemical | | paraffin |
| | | | | | biphenyl | Industry | | |
| | | | | | | Co., Ltd. | | |
| Example 12 | PdTPTAP | Rubrene | PVA | 5CB | 4-cyano-4′- | Tokyo | THF | MCT oil |
| | | | | | pentyl- | Chemical | | |
| | | | | | biphenyl | Industry | | |
| | | | | | | Co., Ltd. | | |
| Example 13 | PtOEP | DPA | PVA | ZLI1052 | Mixed | LCC Co, | THF | — |
| | | | | | liquid | Ltd. | | |
| | | | | | crystal | | | |
| Example 14 | PtOEP | DPA | PVA | ZLI1132-7 | Mixed | LCC Co, | THF | — |
| | | | | | liquid | Ltd. | | |
| | | | | | crystal | | | |
| Example 15 | PtOEP | DPA | PVA | ZLI1083-6 | Mixed | LCC Co, | THF | — |
| | | | | | Liquid | Ltd. | | |
| | | | | | crystal | | | |

| | | | Temperature | | | | | |
|---|---|---|---|---|---|---|---|---|
| | | | (medium | | | | | |
| | | | alone) at | | | | | |
| | | | remaining | T2 | | | | |
| | | | amount of | relaxation | | | Absolute | |
| | Viscosity | Boiling | 95% in | time by | Excitation | Emission | quantum | Average |
| | (23° C.) | point | TG/DTA | TD-NMR | wavelength | wavelength | yield | transmittance |
| No. | [mPa · s] | [° C.] | [° C.] | [μs] | [nm] | [nm] | [%] | [%] |
| Example 7 | 33 | — | 222.09 | 15,020.5 | 532 | 433 | 22 | 78.1 |
| Example 8 | — | — | 248.56 | 155.39 | 532 | 433 | 20 | 73.8 |
| Example 9 | — | — | 201.21 | 162.51 | 532 | 433 | 16.2 | 64.2 |
| Example 10 | — | — | 153.12 | 8,804.6 | 532 | 433 | 18.3 | 77.4 |
| Example 11 | — | — | — | 7,042.3 | 532 | 433 | 17.6 | 80.5 |
| Example 12 | 33 | — | 222.89 | 5,844.32 | 808 | 560 | 5.2 | 66.9 |
| Example 13 | 48 | — | 238.83 | 161.58 | 532 | 433 | 23.4 | 36.8 |
| Example 14 | 24 | — | 206.64 | 1,092.96 | 532 | 433 | 17.8 | 26.5 |
| Example 15 | 18 | — | 210.64 | 82.23 | 532 | 433 | 30.4 | 37.2 |

TABLE 3

| | | | | Color-forming portion solvent (medium) | | | | |
|---|---|---|---|---|---|---|---|---|
| | | Light- | | Monomolecular | | | | |
| | Sensitizing | emitting | | liquid crystal | Compound | Manu- | | |
| No. | component | component | Matrix | compound | name | facturer | Solvent | Additive |
| Example 16 | PtOEP | DPA | PVA | E7 | Mixed liquid | LCC Co, | THF | — |
| | | | | | crystal | Ltd. | | |
| Example 17 | PtOEP | DPA | PVA | E8 | Mixed liquid | LCC Co, | THF | — |
| | | | | | crystal | Ltd. | | |
| Example 18 | PtOEP | DPA | PVA | — | — | — | Tri- | — |
| | | | | | | | caprylin | |
| Example 19 | PtOEP | DPA | — | 5OC8 | 4-cyano-4′- | LCC Co, | THF | — |
| | | | | | pentyloxy- | Ltd. | | |
| | | | | | biphenyl | | | |

| | | | Temperature | | | | | |
|---|---|---|---|---|---|---|---|---|
| | | | (medium alone) | T2 | | | | |
| | | | at remaining | relaxation | | | Absolute | Average |
| | Viscosity | Boiling | amount of 95% | on time by | Excitation | Emission | quantum | trans- |
| | (23° C.) | point | in TG/DTA | TD-NMR | wavelength | wavelength | yield | mittance |
| No. | [mPa · s] | [° C.] | [° C.] | [μs] | [nm] | [nm] | [%] | [%] |
| Example 16 | 52 | — | 235.58 | 93.68 | 532 | 433 | 24.7 | 34.1 |
| Example 17 | 70 | — | 238.38 | 93.69 | 532 | 433 | 31.3 | 35.6 |
| Example 18 | — | — | 258.55 | 45,905.4 | 532 | 433 | 4.0 | 68.8 |
| Example 19 | — | — | — | 15,112.16 | 532 | 433 | 3.2 | 20.3 |

### [Evaluation]

As is apparent from Table 1 to Table 3, it is found that when the T2 relaxation time measured by a spin-echo method through use of TD-NMR at 298 K is less than 210 ms, the absolute quantum yield can be improved, and the up-conversion emission efficiency can be improved.

### INDUSTRIAL APPLICABILITY

The photon up-conversion film and the photon up-conversion body according to the embodiments of the present invention may be suitably used in a solar cell or photovoltaic power generation, a photocatalyst, bioimaging, an optical instrument, a laminate, an energy conversion device, and the like.

1. A photon up-conversion film, comprising a color-forming portion and a matrix,
wherein the color-forming portion contains at least;
a sensitizing component capable of absorbing light in a first wavelength region λ1; and
a light-emitting component capable of radiating light in a second wavelength region λ2 including wavelengths shorter than those of the first wavelength region λ1,
wherein the color-forming portion is dispersed as a dispersion phase in the matrix,
wherein the color-forming portion contains a monomolecular liquid crystal compound,
wherein the matrix includes a water-soluble resin, and
wherein a relaxation time of the photon up-conversion film measured by a spin-echo method through use of time-domain nuclear magnetic resonance (pulse NMR) at 298 K is less than 210 ms.

2. (canceled)

3. (canceled)

4. The photon up-conversion film according to claim 1, wherein the water-soluble resin includes polyethylene oxide and/or a polyvinyl alcohol-based resin.

5. The photon up-conversion film according to claim 1, wherein the color-forming portion contains a solvent having a boiling point of 80° C. or more.

6. The photon up-conversion film according to claim 1, wherein the color-forming portion contains a solvent having a viscosity at 23° C. of 0.6 mPa's or more.

7. (canceled)

8. The photon up-conversion film according to claim 1, wherein the photon up-conversion film comprises 7.00×10⁻⁹ mol to 5.00×10⁻⁶ mol of the sensitizing component, and 5.00×10⁻⁶ mol to 7.00×10⁻⁵ mol of the light-emitting component with respect to 1 g of the resin.

9. A method of producing the photon up-conversion film of claim 1, the method comprising the steps of:
preparing an emulsion from a medium in which the sensitizing component and the light-emitting component are dispersed and/or dissolved, and an aqueous solution containing a water-soluble resin;
applying the emulsion to a substrate to form a coating film; and
drying the coating film.

10. A laminate, comprising the photon up-conversion film of claim 1.

11. An energy conversion device, comprising the photon up-conversion film of claim 1.

12. A photon up-conversion body, comprising a color-forming portion and a matrix,
wherein the color-forming portion contains at least;
a sensitizing component capable of absorbing light in a first wavelength region λ1; and
a light-emitting component capable of radiating light in a second wavelength region λ2 including wavelengths shorter than those of the first wavelength region λ1,
wherein the color-forming portion is dispersed as a dispersion phase in the matrix,
wherein the color-forming portion contains a monomolecular liquid crystal compound,
wherein the matrix includes a water-soluble resin, and
wherein a relaxation time of the photon up-conversion body measured by a spin-echo method through use of time-domain nuclear magnetic resonance (pulse NMR) at 298 K is less than 210 ms.
